(19) United States
(12) Patent Application Publication
(10) Pub. No.: US 2002/0158258 A1
(43) Pub. Date: Oct. 31, 2002

(54) Buffer layer of light emitting semiconductor device and method of fabricating the same

(76) Inventor: Jen-inn Chyi, Ping Chen City (TW)

Correspondence Address: MARTINE & PENILLA, LLP, 710 LAKEWAY DRIVE, SUITE 170, SUNNYVALE, CA, 94085, US

(21) Appl. No.: 10/039,199

(22) Filed: Jan. 4, 2002

(30) Foreign Application Priority Data
Apr. 27, 2001 (TW) 90110239

(51) Int. Cl. H01L 27/15

(52) U.S. Cl. 257/79

(57) ABSTRACT

A buffer layer of a light-emitting semiconductor device and the method of fabricating the same are disclosed. The method includes the steps of: providing a substrate, forming a metal layer on the substrate by supplying a organic metal gas, and forming a metallic nitride layer by supplying a nitride gas to react with part or all of metal layer. The method is characterized in that the reaction gas is supplied separately and the buffer layer is formed with two steps or multiple steps in order to reduce the cleaning times and material waste, thereby realizing a cost-down and efficient manufacturing process.

### BACKGROUND OF THE INVENTION

A. Field of the Invention

The present invention relates to a light emitting semiconductor device and more particularly to a forming method of a buffer layer of a light emitting semiconductor device that can prevent reaction gas crystallizing in gas supplying pipes.

B. Description of the Related Art

In recent years, material such as GaN, InₓGa₁₋ₓN, and Al_{1-x-y}GaₓIn_{y}N has been used in manufacturing the blue light emitting diodes (LEDs). Such LED devices are usually manufactured by providing a substrate on which a buffer layer is formed and then the n-type nitride semiconductor layer such as GaN, InGaN, or AlGaInN is deposited thereon. The buffer layer is used to reduce the stress due to the crystal lattice coefficient difference between the substrate and the epitaxial layer so as to produce a high quality epitaxial layer.

As shown in FIG. 1, the buffer layer 401 on the substrate 400 can be made of material like GaN, AlN, InN, InGaN, AlInN, or AlGaInN and formed by supplying reaction gas, such as NH₃ with TMG, TMA, or TMI, into a MOCVD reacting chamber (not shown) under heat treatment. The reaction gas are generally mixed and supplied simultaneously through a single pipe into the reacting chamber to form the buffer layer 401. Since the pipe's temperature gets higher when it is close to the reaction chamber, the mixed reaction gas easily crystallizes at the outlet of the pipe. Therefore, the outlet of the pipe tends to be clogged frequently. While the buffer layer forming step usually serves as the first step in the epitaxial layer forming process, the crystal clogged in the pipe outlet may fall to surface of the epitaxial layer and results in defects thereon. Therefore, routine cleaning process of the MOCVD equipment, which is time-consuming, is an essential maintenance process. Besides, the crystallization in the pipe outlet will consume part of the reaction gas and decreases the amount of the reacting gas that can use to form the epitaxial layer. Therefore, it will increase the material cost.

The buffer layer is important to the quality of the resulted epitaxial layer. As mentioned above, the conventional method of supplying the mixed gas into the reacting chamber needs to control various process factors, such as gas flow, mixing ratio and deposition rate, that are complicated to control and therefore the difficulties in mass production will increase.

### SUMMARY OF THE INVENTION

The object of the invention is to provide a manufacturing method for buffer layers of light emitting semiconductor devices in order to reduce material waste and the frequency of pipe cleaning during the manufacturing process, thereby realizing a manufacturing method advantaged for its simple process control, good repeatability, low material cost, and high manufacturing yield. The buffer layer of the invention includes a metallic nitride layer and a metal layer, which is formed by successively and separately supplying the single reacting gas into the reaction chamber. The method of the invention includes the steps of: providing a substrate; supplying a organic metal gas to form a metal layer on the substrate; and supplying a nitride gas to form a metallic nitride layer by reacting the nitride gas with part of the metal layer. By repeating the above-mentioned steps, the method of the invention can be performed in a repeated way to form a buffer layer.

### BRIEF DESCRIPTION OF THE DRAWINGS

These and other objects and advantages of the present invention will become apparent by referring to the following description and accompanying drawings wherein:

FIG. 1 is a cross sectional view of a conventional blue light emitting semiconductor device;

FIG. 2 is a cross sectional view of the first embodiment of the invention, wherein the buffer layer is formed by reacting the supplied nitride gas with part of the metal layer;

FIG. 3 is a cross sectional view of the first embodiment of the invention, wherein the buffer layer is formed by reacting the supplied nitride gas with the entire metal layer;

FIG. 4 is a cross sectional view of the second embodiment of the invention, wherein the buffer layer is formed by reacting the supplied nitride gas with part of the metal layer;

FIG. 5 is a cross sectional view of the second embodiment of the invention, wherein the buffer layer is formed by reacting the supplied nitride gas with the entire metal gas;

FIG. 6 is a cross sectional view of the third embodiment of the invention, wherein the buffer layer is formed by reacting the supplied nitride gas with part of the metal layer;

FIG. 7 is a cross sectional view of the third embodiment of the invention, wherein the buffer layer is formed by reacting the supplied nitride gas with the entire metal gas.

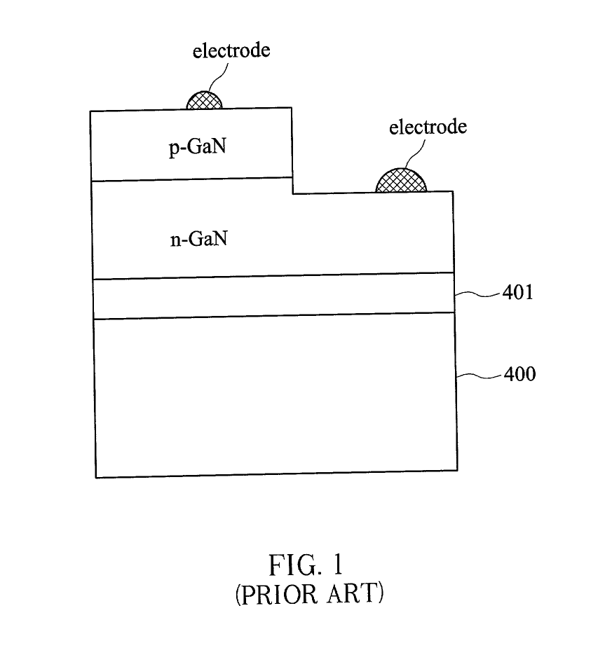

### DETAIL DESCRIPTION OF THE INVENTION

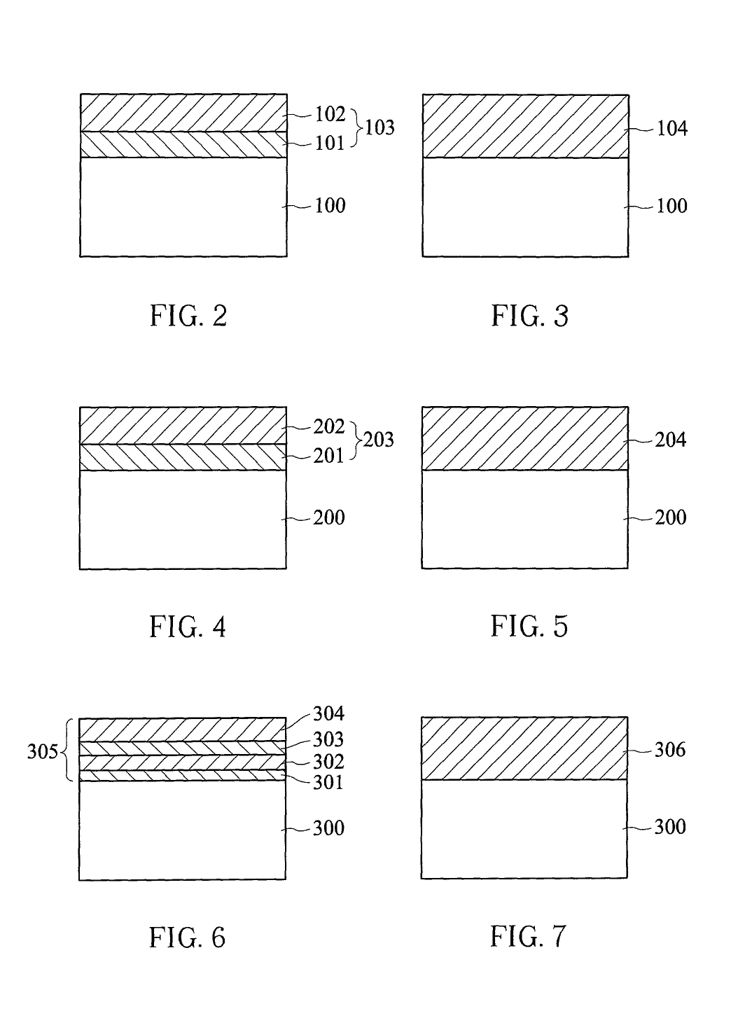

The first embodiment of the invention is shown in FIG. 2 and FIG. 3. The method of forming a buffer layer of a light emitting semiconductor device according to the first embodiment includes the steps of: providing a sapphire substrate 100, forming an In layer 101 on substrate 100 by supplying an organic metal gas, such as trimethylindium (TMI), and forming a InN layer 102 by supplying a nitride gas, such as NH₃, to react with the In layer 101. The organic metal gas and the nitride gas are supplied into the MOCVD chamber (not shown) separately. In FIG. 2, the In layer 101 denotes the remained In layer, which does not reacted with the supplied nitride gas.

Thus, the buffer layer 103 formed by the method of the first embodiment includes the InN layer 102 and the remained In layer 101, which is not reacted with the nitride gas. That is, the method of the first embodiment is characterized in that the reaction gas TMI and NH₃ are supplied into the MOCVD chamber separately and successively. Therefore, the crystallization results from the reaction between TMI and NH₃ around the outlet of the supplying pipe before transporting into the MOCVD chamber can be avoided. As a result, the cleaning times of the gas pipe can be decreased, thus simplifying the manufacturing process and reducing the maintenance cost.

The thickness of InN layer 102 relative to In layer 101 left without reacting with the nitride gas can be adjusted according to the requirement of the process or the characteristic of end products. That is, it is possible that the supplied NH₃ gas would react with the entire In layer to form the InN layer 104 as a whole, as shown in FIG. 3. Namely, the InN 104 layer is provided with a structure similar to the conventional buffer layer while it is formed without the pipe clogging of MOCVD chamber.

The second embodiment of the invention is shown in FIG.4 and FIG.5. The method of forming a buffer layer of a light emitting semiconductor device according to the second embodiment includes the steps of: providing a sapphire substrate 200, forming a Al layer 201 on substrate 200 by supplying an organic metal gas, such as trimethylaluminum (TMA), and forming a AlN layer 202 by supplying a nitride gas, such as NH₃, to react with the Al layer 202. In FIG.4, the Al layer 201 denotes the remained Al layer, which does not reacted with the supplied nitride gas. The resulted buffer layer 203 is consisted of the remained Al layer 201 and the AlN layer 202.

Similar to the first embodiment, the thickness of the AlN layer 202 relative to the Al layer 201 left without reacting with the nitride gas can be adjusted according to the requirement of the process or the characteristic of end products. That is, it is possible that the supplied NH₃ gas would react with the entire Al layer 201 to form the AlN layer 204 as a whole, as shown in FIG. 5.

The second embodiment differs with the first embodiment in that the metal layer is replaced with the Al layer and the reaction gas is replaced with the TMA gas. In addition to aluminum (Al), boron (B) and gallium (Ga) also can be used to form the buffer layers, i.e., BN and GaN, respectively. Thus, all kinds of the metallic compound gas used for forming the conventional buffer layer, such as AlCl₃, GaCl₃, TMG, TEG, TMA, TEA, DEAIE, TMI, TEIn and so on, can be utilized in the method of the invention. Meanwhile, the nitride gas can be any gas/organic gas containing nitrogen, such as N₂, NH₃, t-BA, DMH, and so on.

In addition to sapphire, the substrate used in the above-mentioned embodiments can be one of SiC, Si, GaAs, InP, AlN, GaP, GaN, ZnSe, and so on.

The second embodiment of the invention is shown in FIG. 6 and FIG. 7. As shown in FIG. 6, the manufacturing steps mentioned in the first or second embodiment are repeated twice to form the buffer layer 305, which consists of the In layer (or the Al layer) 301, the InN layer (or the AN layer) 302, the In layer (or the Al layer) 303, and the InN layer (or the AlN layer) 304. In FIG. 6, the Buffer layer 305 is formed by the nitride gas reacting with part of each metal layer while the buffer layer 306 shown in FIG. 7 is formed by the nitride gas reacting with each of the entire metal layer. The thickness of buffer layer 305 or 306 is substantially equal to that of the buffer layer 103 in the first embodiment or the buffer layer 203 in the second embodiment. Thus, the third embodiment of the invention emphasizes that the method of manufacturing the buffer layer includes the steps of repeating the method disclosed in the first or second embodiment several times in view of optimizing the process performance.

As mentioned above, the method of the invention perform the gas supplying in a separate way so as to reduce the crystallization at the outlet of the MOCVD gas pipe. Therefore, the material wasted during the forming process is reduced and the manufacturing yield is also improved. If there are more than three kinds of supplying gas for forming the buffer layer, the method of the invention is also proper for the object mentioned above. For example, such buffer layer which is formed by more than three kinds of reaction gas could be AlGaN, AlInN, InGaN, AlBN, InBN, AlInGaN, AlGaBN, AlInBN, InGaBN, AlInGaBN, etc.

While this invention has been described with reference to an illustrative embodiment, it is not intended that this description be construed in a limiting sense. Various modifications and combinations of the illustrative embodiment, as well as other embodiments of the invention, will be apparent to persons skilled in the art upon reference to the description. It is therefore intended that the appended claims encompass any such modifications or embodiments.

What is claimed is:

1. A buffer layer of a light emitting semiconductor device, wherein the light emitting semiconductor device includes a substrate, said buffer layer disposed on the substrate, an light emitting semiconductor layer, and electrodes for inputting voltage, said buffer layer comprising:
a metal layer formed on said substrate; and
a metallic nitride layer, which is formed on said metal layer by transforming part of said metal layer into metallic nitride layer.

2. The buffer layer as claimed in claim 1, wherein said substrate is made of material selected from the group of sapphire, SiC, silicon, GaAs, InP, AlN, GaP, GaN, and ZnSe.

3. The buffer layer as claimed in claim 1, wherein said metal layer is an Indium (In) layer.

4. The buffer layer as claimed in claim 3, wherein said metallic nitride layer is an InN layer.

5. The buffer layer as claimed in claim 1, wherein said metal layer is an aluminum layer.

6. The buffer layer as claimed in claim 5, wherein said metallic nitride layer is an AlN layer.

7. The buffer layer as claimed in claim 1, wherein said metal layer is a boron layer.

8. The buffer layer as claimed in claim 1, wherein said metallic nitride layer is a BN layer.

9. The buffer layer as claimed in claim 1, wherein said metal layer is a gallium layer.

10. The buffer layer as claimed in claim 1, wherein said metallic nitride layer is a GaN layer.

11. A method for manufacturing a buffer layer of a light emitting semiconductor device, comprising the steps of:
providing a substrate;
forming a metal layer on said substrate by supplying an organic metal gas; and
forming a metallic nitride layer by supplying a nitride gas to react with part of said metal layer.

12. The method as claimed in claim 11, wherein said substrate is made of material selected from the group of sapphire, SiC, silicon, GaAs, InP, AlN, GaP, GaN, and ZnSe.

13. The method as claimed in claim 11, wherein said metal layer is an Indium (In) layer.

14. The buffer layer as claimed in claim 13, wherein said metallic nitride layer is an InN layer.

15. The buffer layer as claimed in claim 11, wherein said metal layer is an aluminum layer.

16. The buffer layer as claimed in claim 15, wherein said metallic nitride layer is an AlN layer.

17. The buffer layer as claimed in claim 11, wherein said metal layer is a boron layer.

18. The buffer layer as claimed in claim 17, wherein said metallic nitride layer is a BN layer.

19. The buffer layer as claimed in claim 11, wherein said metal layer is a gallium layer.

20. The buffer layer as claimed in claim 19, wherein said metallic nitride layer is a GaN layer.

21. A method for manufacturing a buffer layer of a light emitting semiconductor device, comprising the steps of:
providing a substrate;
forming a metal layer on said substrate by supplying a metal gas; and
form a metallic nitride layer by supplying a nitride gas to react with said metal layer.

22. The method as claimed in claim 21, wherein said substrate is made of material selected from the group of sapphire, SiC, silicon, GaAs, InP, AlN, GaP, GaN, and ZnSe.

23. The method as claimed in claim 21, wherein said metal layer is an Indium (In) layer.

24. The buffer layer as claimed in claim 23, wherein said metallic nitride layer is an InN layer.

25. The buffer layer as claimed in claim 21, wherein said metal layer is an aluminum layer.

26. The buffer layer as claimed in claim 25, wherein said metallic nitride layer is an AlN layer.

27. The buffer layer as claimed in claim 21, wherein said metal layer is a boron layer.

28. The buffer layer as claimed in claim 27, wherein said metallic nitride layer is a BN layer.

29. The buffer layer as claimed in claim 21, wherein said metal layer is a gallium layer.

30. The buffer layer as claimed in claim 29, wherein said metallic nitride layer is a GaN layer.

31. A buffer layer of a light emitting semiconductor device, wherein the light emitting semiconductor device includes a substrate, said buffer layer disposed on the substrate, an light emitting semiconductor layer, and electrodes for inputting voltage, said buffer layer is manufactured by the method claimed in claim 11.

32. A buffer layer of a light emitting semiconductor device, wherein the light emitting semiconductor device includes a substrate, said buffer layer disposed on the substrate, an light emitting semiconductor layer, and electrodes for inputting voltage, said buffer layer is manufactured by the method claimed in claim 21.
